(19) United States
(12) Patent Application Publication
(10) Pub. No.: US 2026/0351532 A1
(43) Pub. Date: Nov. 5, 2026

(54) CLEANING METHOD AND PLASMA PROCESSING APPARATUS

(71) Applicant: Tokyo Electron Limited, Tokyo (JP)

(72) Inventors: Hiroki SATO, Miyagi (JP); Takumi IMAHASHI, Miyagi (JP)

(73) Assignee: Tokyo Electron Limited, Tokyo (JP)

(21) Appl. No.: 19/707,645

(22) Filed: Jun. 15, 2026

Related U.S. Application Data
(63) Continuation of application No. PCT/JP2025/019242, filed on May 28, 2025.

(30) Foreign Application Priority Data
Jun. 11, 2024 (JP) 2024-094442

(51) Int. Cl. H01J 37/32

(52) U.S. Cl. CPC H01J 37/32862; H01J 37/32449; H01J 37/32642; H01J 37/32715; H01J 37/32834; H01J 2237/2007

(57) ABSTRACT

A cleaning method for a plasma processing apparatus includes: a step of supporting a substrate on a substrate support disposed in a chamber, the substrate support comprising a first region supporting the substrate and a second region supporting an edge ring; a step of adjusting a potential of an impedance adjusting electrode such that a potential of the second region becomes lower than a potential of the first region by controlling an impedance adjuster connected to the impedance adjusting electrode provided in the second region; a step of supplying a cleaning gas into the chamber; a step of generating plasma from the cleaning gas by supplying high-frequency power for plasma generation into the chamber; and a step of cleaning a member in the chamber by supplying bias power into the chamber.

### CROSS-REFERENCE TO RELATED APPLICATIONS

This application is a continuation of International Application No. PCT/JP2025/019242, filed on May 28, 2025 which claims the benefit of priority of the prior Japanese Patent Application No. 2024-094442, filed on Jun. 11, 2024, the entire contents of each are incorporated herein by reference.

### BACKGROUND

Japanese Patent Application Laid-open No. 2021-12951 discloses “A cleaning method including the steps of removing a residue of a typical semiconductor material element group in a chamber with a halogen-containing gas plasma, removing the residues of Group 12 and Group 13 metal elements and Group 14 and Group 15 metal elements in the chamber with a hydrocarbon-containing gas plasma, and removing a C-containing substance in the chamber with an O-containing gas plasma, and before or after the step of removing with the halogen-containing gas plasma, a step of removing with the hydrocarbon-containing gas plasma and the step of removing with the O-containing gas plasma are performed a predetermined number of times X (X≥1) in the order mentioned”.

### SUMMARY

According to an aspect of the present disclosure, there is provided a cleaning method for a plasma processing apparatus, the method including: a step of supporting a substrate on a substrate support disposed in a chamber, the substrate support comprising a first region supporting the substrate and a second region supporting an edge ring;
a step of adjusting a potential of an impedance adjusting electrode such that a potential of the second region becomes lower than a potential of the first region by controlling an impedance adjuster connected to the impedance adjusting electrode provided in the second region; a step of supplying a cleaning gas into the chamber; a step of generating plasma from the cleaning gas by supplying high-frequency power for plasma generation into the chamber; and a step of cleaning a member in the chamber by supplying bias power into the chamber.

### BRIEF DESCRIPTION OF DRAWINGS

FIG. 1 is a diagram illustrating an example of a plasma processing system according to an embodiment of the present disclosure;

FIG. 2 is a schematic cross-sectional view illustrating an example of the configuration of a plasma processing apparatus according to the present embodiment;

FIG. 3 is a diagram illustrating an example of the configuration of an electrode in the embodiment;

FIG. 4 is a diagram illustrating an example of an equivalent circuit of an electrostatic chuck and plasma in the embodiment;

FIG. 5 is a diagram illustrating an example of the circuit configuration of an impedance adjusting mechanism in the embodiment;

FIG. 6 is a diagram illustrating an example of the concept of an RF signal flow in a case where the electrostatic capacitance of a variable capacitor on a ring support surface side is reduced;

FIG. 7 is a diagram illustrating an example of the concept of an RF signal flow in a case where the electrostatic capacitance of a variable capacitor on the ring support surface side is increased;

FIG. 8 is a graph illustrating an example of the relationship between the electrostatic capacitance of the variable capacitor on the ring support surface side and the potentials of a substrate and an edge ring in the embodiment;

FIG. 9 is a diagram illustrating an example of the concept of an RF signal flow in a case where the electrostatic capacitance of a variable capacitor on a substrate support surface side is increased;

FIG. 10 is a graph illustrating an example of the relationship between the electrostatic capacitance of the variable capacitor on the substrate support surface side and the potentials of the substrate and the edge ring in the embodiment;

FIG. 11 is a flowchart illustrating an example of a cleaning process in the embodiment;

FIG. 12 is a flowchart illustrating an example of a waferless cleaning process according to the embodiment; and

FIG. 13 is a flowchart illustrating an example of an edge ring replacement process according to the embodiment.

### DETAILED DESCRIPTION

Hereinafter, exemplary embodiments of a cleaning method and a plasma processing apparatus disclosed in the present application will be described in detail with reference to the drawings. Note that the disclosed technology is not limited by the following exemplary embodiments.

The present disclosure relates to a cleaning method and a plasma processing apparatus.

The present disclosure provides a cleaning method and a plasma processing apparatus capable of suppressing wear of members in a chamber while supplying large bias power.

In a plasma processing apparatus, a deposit containing metal (aluminum, yttrium, etc.) may adhere to the inside of a chamber in a plasma process. The deposit is removed in a cleaning process. However, for example, in a case where a deposit containing metal and adhering to a side wall in the chamber is to be removed, a plasma sheath on a member, serving as the ground, such as a side wall in the chamber, is thin, which makes it difficult to be cleaned as compared with being on a substrate support unit where bias power is directly supplied. Therefore, in order to clean these members serving as the ground, it is required to increase ion energy of plasma, namely, to supply large bias power. However, when large bias power is supplied, for example, wear of a member such as an edge ring held by the substrate support unit increases. Therefore, it is expected to suppress wear of members in the chamber while supplying large bias power.

### Configuration of Plasma Processing System

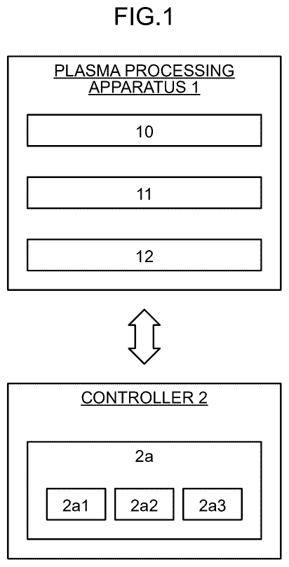

FIG. 1 is a diagram illustrating an example of a plasma processing system according to an embodiment of the present disclosure. In one embodiment, a plasma processing system includes a plasma processing apparatus 1 and a controller 2. The plasma processing system is an example of a substrate processing system, and the plasma processing apparatus 1 is an example of a substrate processing apparatus. The plasma processing apparatus 1 includes a plasma processing chamber 10, a substrate support unit 11, and a plasma generation unit 12. The plasma processing chamber 10 has a plasma processing space. The plasma processing chamber 10 also has at least one gas supply port for supplying at least one type of processing gas to the plasma processing space and at least one gas discharge port for discharging the gas from the plasma processing space. The gas supply port is connected to a gas supply unit 20 to be described later, and the gas discharge port is connected to an exhaust system 40 to be described later. The substrate support unit 11 is disposed in the plasma processing space and has a substrate support surface for supporting a substrate.

The plasma generation unit 12 generates plasma from at least one type of processing gas supplied into the plasma processing space. The plasma formed in the plasma processing space may be capacitively coupled plasma (CCP), inductively coupled plasma (ICP), electron-cyclotron-resonance plasma (ECR), helicon wave plasma (HWP), surface wave plasma (SWP), or the like. In addition, various types of plasma generation units including an alternating current (AC) plasma generation unit and a direct current (DC) plasma generation unit may be used. In an embodiment, an AC signal (AC power) used in the AC plasma generation unit has a frequency in the range of 100 kHz to 10 GHz. Therefore, the AC signal includes a radio frequency (RF) signal and a microwave signal. In an embodiment, the RF signal has a frequency in the range of 100 kHz to 150 MHz.

The controller 2 processes a computer-executable instruction that causes the plasma processing apparatus 1 to execute the various processes described in the present disclosure. The controller 2 can be configured to control each element of the plasma processing apparatus 1 such that various processes described herein are executed. In one embodiment, a part or the entirety of the controller 2 may be included in the plasma processing apparatus 1. The controller 2 may include a processing unit 2a1, a storage 2a2, and a communication interface 2a3. The controller 2 is implemented by, for example, a computer 2a. The processing unit 2a1 can be configured to perform various control operations by reading a program from the storage 2a2 and executing the read program. This program may be stored in the storage 2a2 in advance, or may be acquired via a medium when necessary. The acquired program is stored in the storage 2a2, and is read from the storage 2a2 and executed by the processing unit 2a1. The medium may be various storage media readable by the computer 2a, or may be a communication line connected to the communication interface 2a3. The processing unit 2a1 may be a central processing unit (CPU). The storage 2a2 may include a random access memory (RAN), a read only memory (ROM), a hard disk drive (HDD), a solid state drive (SSD), or a combination thereof. The communication interface 2a3 may communicate with the plasma processing apparatus 1 via a communication line such as a local area network (LAN). The functionality of the elements disclosed herein may be implemented using circuitry or processing circuitry which includes general purpose processors, special purpose processors, integrated circuits, ASICs (“Application Specific Integrated Circuits”), FPGAs (“Field-Programmable Gate Arrays”), conventional circuitry and/or combinations thereof which are programmed, using one or more programs stored in one or more memories, or otherwise configured to perform the disclosed functionality. Processors and controllers are considered processing circuitry or circuitry as they include transistors and other circuitry therein. In the disclosure, the circuitry, units, or means are hardware that carry out or are programmed to perform the recited functionality. The hardware may be any hardware disclosed herein which is programmed or configured to carry out the recited functionality. There is a memory that stores a computer program which includes computer instructions. These computer instructions provide the logic and routines that enable the hardware (e.g., processing circuitry or circuitry) to perform the method disclosed herein. This computer program can be implemented in known formats as a computer-readable storage medium, a computer program product, a memory device, a record medium, such as a CD-ROM or DVD, and/or the memory of a FPGA or ASIC.

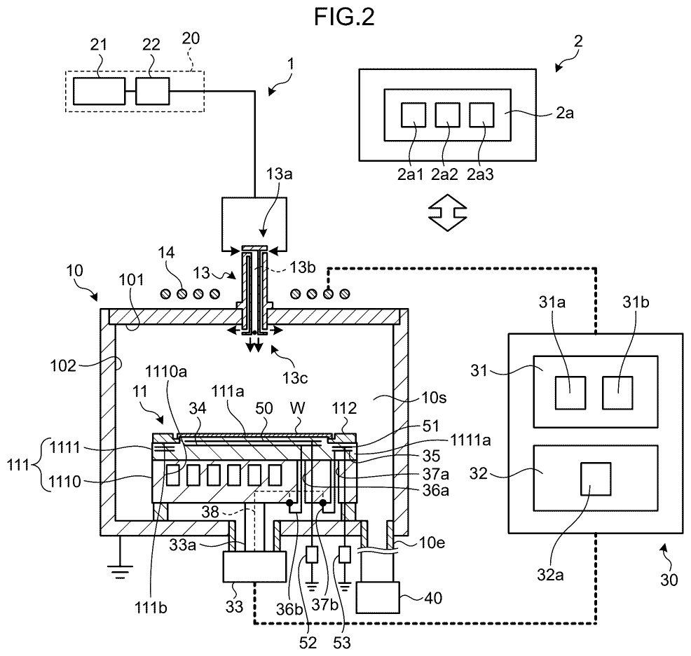

Hereinafter, a configuration example of a plasma processing apparatus of an inductively-coupled type as an example of the plasma processing apparatus 1 will be described. FIG. 2 is a schematic cross-sectional view illustrating an example of the configuration of the plasma processing apparatus according to the present embodiment.

The plasma processing apparatus 1 of the inductively-coupled type includes a plasma processing chamber 10, a gas supply unit 20, a power supply 30, and an exhaust system 40. The plasma processing chamber 10 includes a dielectric window 101. The plasma processing apparatus 1 includes a substrate support unit 11, a gas introduction unit, and an antenna 14. The substrate support unit 11 is an example of a substrate support and is disposed in the plasma processing chamber 10. The antenna 14 is disposed on or above the plasma processing chamber 10 (i.e., on or above the dielectric window 101). The plasma processing chamber 10 has a plasma processing space 10s defined by the dielectric window 101, a side wall 102 of the plasma processing chamber 10, and the substrate support unit 11. The plasma processing chamber 10 is grounded.

The substrate support unit 11 includes a body section 111 and a ring assembly 112. The body section 111 has a central region 111a for supporting a substrate W and an annular region 111b for supporting the ring assembly 112. A wafer is an example of the substrate W. The annular region 111b of the body section 111 surrounds the central region 111a of the body section 111 in plan view. The substrate W is disposed on the central region 111a of the body section 111, and the ring assembly 112 is disposed on the annular region 111b of the body section 111 in such a manner as to surround the substrate W on the central region 111a of the body section 111. Therefore, the central region 111a is also referred to as a substrate support surface for supporting the substrate W, and the annular region 111b is also referred to as a ring support surface for supporting the ring assembly 112. Note that central region 111a is an example of a first region, and annular region 111b is an example of a second region. In the following description, the central region 111a may be referred to as a substrate support surface 111a, and the annular region 111b may be referred to as a ring support surface 111b.

In one embodiment, the body section 111 includes a base 1110 and an electrostatic chuck 1111. The base 1110 includes a conductive member. The conductive member of the base 1110 can function as a part of an electrical path 38 connected with a first bias electrode 34 and a second bias electrode 35 described later. A power supply line 33a is connected to a bottom section of the base 1110. The electrical path 38 also includes the power supply line 33a. The electrostatic chuck 1111 is disposed on the base 1110. The electrostatic chuck 1111 includes a ceramic member 1111a and an electrostatic electrode (not illustrated) disposed in the ceramic member 1111a. The ceramic member 1111a has a central region 111a. In one embodiment, the ceramic member 1111a also has the annular region 111b. Note that another member surrounding the electrostatic chuck 1111, such as an annular electrostatic chuck or an annular insulating member, may have the annular region 111b. In this case, the ring assembly 112 may be disposed on the annular electrostatic chuck or the annular insulating member, or may be disposed on both the electrostatic chuck 1111 and the annular insulating member. In addition, at least one RF/DC electrode coupled to an RF power supply 31 and/or a DC power supply 32 described later may be disposed in the ceramic member 1111a. In this case, at least one RF/DC electrode functions as a bias electrode. That is, the first bias electrode 34 and the second bias electrode 35 to be described later are electrically connected to the RF power supply 31 and/or the DC power supply 32 via the electrical path 38. Note that the conductive member of the base 1110 and at least one RF/DC electrode may function as a plurality of bias electrodes. In addition, an electrostatic electrode (not illustrated) may function as a bias electrode, and the first bias electrode 34 may function as an electrostatic electrode. Therefore, the substrate support unit 11 includes at least one bias electrode.

The ring assembly 112 includes one or a plurality of annular members. In one embodiment, one or a plurality of annular members include one or a plurality of edge rings and at least one cover ring. The edge ring is formed of a conductive material or an insulating material, and the cover ring is formed of an insulating material.

In addition, the substrate support unit 11 may include a temperature control module configured to adjust at least one of the electrostatic chuck 1111, the ring assembly 112, or the substrate W to a target temperature. The temperature control module may include a heater, a heat transfer medium, a flow channel 1110a, or a combination thereof. A heat-transfer fluid such as brine or gas flows through the flow channel 1110a. In one embodiment, the flow channel 1110a is formed in the base 1110, and one or a plurality of heaters are arranged in the ceramic member 1111a of the electrostatic chuck 1111. Furthermore, the substrate support unit 11 may include a heat-transfer gas supply unit configured to supply a heat-transfer gas to a gap between the back side of the substrate W and the central region 111a.

The electrostatic chuck 1111 includes a first impedance adjusting electrode 50 and the first bias electrode 34 inside thereof in the order mentioned from the substrate support surface 111a side below the substrate support surface 111a, and is formed of a dielectric such as ceramic. In addition, the electrostatic chuck 1111 includes a second impedance adjusting electrode 51 and the second bias electrode 35 in the order mentioned from the ring support surface 111b side below the ring support surface 111b. The first bias electrode 34 is connected with, for example, the bottom section of the base 1110 via a conductor 36b passing through a through hole 36a of the base 1110. An insulating sleeve (not illustrated) is provided inside the through hole 36a, and the base 1110 and the conductor 36b are electrically insulated in the through hole 36a. The second bias electrode 35 is connected to, for example, the bottom section of the base 1110 via a conductor 37b passing through a through hole 37a of the base 1110. An insulating sleeve (not illustrated) is provided inside the through hole 37a, and the base 1110 and the conductor 37b are electrically insulated in the through hole 37a.

That is, the first bias electrode 34 and the second bias electrode 35 are connected to a matching circuit 33 to be described later via the conductors 36b and 37b, the base 1110, and the power supply line 33a, whereby an electrical path 38 is formed. Note that connections between the base 1110 and each of the first bias electrode 34 and the second bias electrode 35 are not limited to the conductive member, and may be any method capable of supplying a bias RF signal such as magnetic resonance, capacitive coupling, and inductive coupling. That is, the electrical path 38 connects a bias power supply (for example, second RF generation unit 31b described later), the first bias electrode 34, and the second bias electrode 35. In the electrical path 38, the second RF generation unit 31b to be described later may not be connected to the base 1110, and the second RF generation unit 31b may be directly connected to the first bias electrode 34 and the second bias electrode 35.

The first impedance adjusting electrode 50 is grounded via an impedance adjusting mechanism 52. The impedance adjusting mechanism 52 adjusts the amount of a part of an RF signal (electric bias) supplied from the first bias electrode 34 to flow to the ground (earth) side. By adjusting the amount of the RF signal flowing to the ground side by the first impedance adjusting electrode 50, the potential of the substrate W is adjusted and used for controlling the tilt angle and/or adjusting the etching rate. In addition, with the first impedance adjusting electrode 50 adjusting the amount of the RF signal flowing to the ground side, the wear of the substrate support surface 111a is suppressed in cleaning of the substrate support surface 111a and the ring assembly 112. At least one first impedance adjusting electrode 50 is provided in the electrostatic chuck 1111. The impedance adjusting mechanism 52 is connected to the first impedance adjusting electrode 50. In a case where a plurality of first impedance adjusting electrodes 50 are provided, for example, two or more first impedance adjusting electrodes 50 are provided in the circumferential direction of the substrate support unit 11, and a number of impedance adjusting mechanisms 52 are also provided, the number of impedance adjusting mechanisms 52 corresponding to the number of the first impedance adjusting electrodes 50. In addition, two or more first impedance adjusting electrodes 50 may be provided in the radial direction of the substrate support unit 11. Furthermore, two or more first impedance adjusting electrodes 50 may be provided in each of the circumferential direction and the radial direction of the substrate support unit 11. Note that the first impedance adjusting electrodes 50 are arranged in such a manner as to be parallel to the first bias electrode 34.

The second impedance adjusting electrode 51 is grounded via an impedance adjusting mechanism 53. The impedance adjusting mechanism 53 adjusts the amount of a part of the RF signal (electric bias) supplied from the second bias electrode 35 to flow to the ground (earth) side. By adjusting the amount of the RF signal flowing to the ground side by the second impedance adjusting electrode 51, the potential of the ring assembly 112 is adjusted and used for controlling the tilt angle and/or adjusting the etching rate. In addition, by adjusting the amount of the RF signal flowing to the ground side by the second impedance adjusting electrode 51, even if bias power capable of cleaning the side wall 102 of the plasma processing chamber 10 is supplied, wear of the ring assembly 112 can be suppressed. At least one second impedance adjusting electrode 51 is provided in the electrostatic chuck 1111. In a case where a plurality of second impedance adjusting electrodes 51 are provided, for example, two or more second impedance adjusting electrodes 51 are provided in the circumferential direction of the substrate support unit 11, and a number of impedance adjusting mechanisms 53 are also provided, the number of impedance adjusting mechanisms 53 corresponding to the number of the second impedance adjusting electrodes 51. In addition, two or more second impedance adjusting electrodes 51 may be provided in the radial direction of the substrate support unit 11. Furthermore, two or more second impedance adjusting electrodes 51 may be provided in each of the circumferential direction and the radial direction of the substrate support unit 11. Note that the second impedance adjusting electrodes 51 are arranged in such a manner as to be parallel to the second bias electrode 35.

With the first bias electrode 34 and the second bias electrode 35 arranged as close as possible to the substrate W and the ring assembly 112, respectively, the impedances of capacitors including the substrate W, the ring assembly 112, the ceramic of the electrostatic chuck 1111, and the electrodes are reduced. As a result, the potential difference between the first bias electrode 34 and the substrate W and the potential difference between the second bias electrode 35 and the ring assembly 112 are each reduced. Similarly, the impedance of a capacitor including the first bias electrode 34 and the first impedance adjusting electrode 50 and the impedance of a capacitor including the second bias electrode 35 and the second impedance adjusting electrode 51 are also each reduced. In addition, the impedance of a capacitor including the first impedance adjusting electrode 50 and the substrate W and the impedance of a capacitor including the second impedance adjusting electrode 51 and the ring assembly 112 are also each reduced.

Note that it is not necessary to provide both of the impedance adjusting mechanisms 52 and 53. In a case where one of the impedance adjusting mechanisms 52 and 53 is not provided, the first impedance adjusting electrode 50 or the second impedance adjusting electrode 51, whichever is on the side where one of the impedance adjusting mechanisms 52 and 53 is not provided, may be connected to the ground via impedance of a predetermined value. Alternatively, the first impedance adjusting electrode 50 or the second impedance adjusting electrode 51, whichever is on the side where one of the impedance adjusting mechanisms 52 and 53 is not provided, may be in a floating state without being connected to the ground.

The gas introduction unit is configured to introduce at least one type of processing gas from the gas supply unit 20 into the plasma processing space 10s. In one embodiment, the gas introduction unit includes a center gas injector (CGI) 13. The center gas injector 13 is disposed above the substrate support unit 11 and is attached to a central opening formed in the dielectric window 101. The center gas injector 13 has at least one gas supply port 13a, at least one gas flow channel 13b, and at least one gas introduction port 13c. The processing gas supplied to the gas supply port 13a passes through the gas flow channel 13b and is introduced into the plasma processing space 10s from the gas introduction port 13c. The gas introduction unit may include one or a plurality of side gas injectors (SGIs) attached to one or a plurality of openings formed in the side wall 102 in addition to or instead of the center gas injector 13.

The gas supply unit 20 may include at least one gas source 21 and at least one flow controller 22. In one embodiment, the gas supply unit 20 is configured to supply at least one processing gas from a corresponding gas source 21 to the gas introduction unit via a corresponding flow controller 22. Each flow controller 22 may include, for example, a mass flow controller or a pressure-control type flow controller. Additionally, the gas supply unit 20 may include at least one flow modulation device that modulates or pulses the flow rate of the at least one processing gas. Note that the gas supply unit 20 is configured to supply a cleaning gas as the processing gas in the cleaning process. Examples of the cleaning gas include tetrafluoromethane gas, oxygen gas, and argon gas.

The power supply 30 includes the RF power supply 31 coupled to the plasma processing chamber 10 via at least one impedance matching circuit. The RF power supply 31 supplies at least one RF signal (RF power) to at least one first bias electrode 34, the second bias electrode 35, and the antenna 14. As a result, plasma is formed from at least one processing gas supplied to the plasma processing space 10s. Therefore, the RF power supply 31 can function as at least a part of the plasma generation unit 12. In addition, by supplying a bias RF signal to at least one first bias electrode 34 and the second bias electrode 35, a bias potential is generated in the substrate W, whereby ions in the formed plasma can be drawn into the substrate W.

In one embodiment, the RF power supply 31 includes a first RF generation unit 31a and a second RF generation unit 31b. The first RF generation unit 31a is coupled to the antenna 14 via at least one impedance matching circuit and generates a source RF signal (source RF power) for plasma generation. In one embodiment, the source RF signal has a frequency in a range of 10 MHz to 150 MHz. In one embodiment, the first RF generation unit 31a may generate a plurality of source RF signals having different frequencies. The generated one or more source RF signals are supplied to the antenna 14. Note that the first RF generation unit 31a is an example of a source power supply, and the source RF signal is an example of high-frequency power.

The second RF generation unit 31b is coupled to the first bias electrode 34 and the second bias electrode 35 via a matching circuit 33, the power supply line 33a, and the base 1110, and generates the bias RF signal (bias RF power). The generated bias RF signal is supplied to the first bias electrode 34 and the second bias electrode 35. The frequency of the bias RF signal may be the same as or different from the frequency of the source RF signal. In one embodiment, the bias RF signal has a lower frequency than the frequency of the source RF signal. In one embodiment, the bias RF signal has a frequency in a range of 100 kHz to 60 MHz. In one embodiment, the second RF generation unit 31b may be configured to generate a plurality of bias RF signals having different frequencies. The generated one or more bias RF signals are supplied to at least one first bias electrode 34 and the second bias electrode 35. Furthermore, in various embodiments, at least one of the source RF signal or the bias RF signal may be pulsed. Note that the second RF generation unit 31b is an example of the bias power supply, and the bias RF signal is an example of the bias power.

The matching circuit 33 is connected to the second RF generation unit 31b and the substrate support unit 11 (base 1110). The matching circuit 33 allows the bias RF signal to be supplied from the second RF generation unit 31b to the substrate support unit 11 via the matching circuit 33. In addition, the matching circuit 33 allows a bias DC signal described later to be supplied from a bias DC generation unit 32a to be described later to the substrate support unit 11 via the matching circuit 33.

The power supply 30 may also include the DC power supply 32 coupled to the plasma processing chamber 10. The DC power supply 32 includes the bias DC generation unit 32a. In one embodiment, the bias DC generation unit 32a is connected to at least one first bias electrode 34 and the second bias electrode 35 and generates the bias DC signal. The generated bias DC signal is applied to at least one first bias electrode 34 and the second bias electrode 35. Note that the bias DC generation unit 32a is an example of a bias power supply, and the bias DC signal is an example of bias power.

In various embodiments, the bias DC signal may be pulsed. In this case, a sequence of voltage pulses is applied to at least one first bias electrode 34 and the second bias electrode 35. The voltage pulse may have a pulse waveform of a rectangle, a trapezoid, a triangle, or a combination thereof. In one embodiment, a waveform generation unit for generating a sequence of voltage pulses from a DC signal is connected between the bias DC generation unit 32a and at least one first bias electrode 34 and the second bias electrode 35. Therefore, the bias DC generation unit 32a and the waveform generation unit constitute a voltage pulse generation unit. The voltage pulse may have a positive polarity or a negative polarity. The sequence of voltage pulses may include one or a plurality of positive voltage pulses and one or a plurality of negative voltage pulses in one period. Note that the bias DC generation unit 32a may be provided in addition to the RF power supply 31, or may be provided instead of the second RF generation unit 31b. The bias RF signal and the bias DC signal (bias power) may be capable of cleaning the side wall 102 in the plasma processing chamber 10. Furthermore, the bias RF signal and the bias DC signal may be capable of cleaning the substrate support surface 111a and the edge ring (ring assembly 112). Note that the bias power may include one or more of a high-frequency signal and a pulsed DC signal. In addition, the bias power is more effective at a low frequency.

The antenna 14 includes one or a plurality of coils. In one embodiment, the antenna 14 may include an outer coil and an inner coil arranged coaxially. In this case, the RF power supply 31 may be connected to both the outer coil and the inner coil, or may be connected to either one of the outer coil or the inner coil. In the former case, the same RF generation unit may be connected to both the outer coil and the inner coil, or separate RF generation units may be each connected to one of the outer coil or the inner coil.

The exhaust system 40 can be connected to a gas discharge port 10e provided, for example, at a bottom section of the plasma processing chamber 10. The exhaust system 40 may include a pressure regulating valve and a vacuum pump. The pressure in the plasma processing space 10s is adjusted by the pressure regulating valve. The vacuum pump may include a turbomolecular pump, a dry pump, or a combination thereof.

### Potential on Substrate Support Unit 11

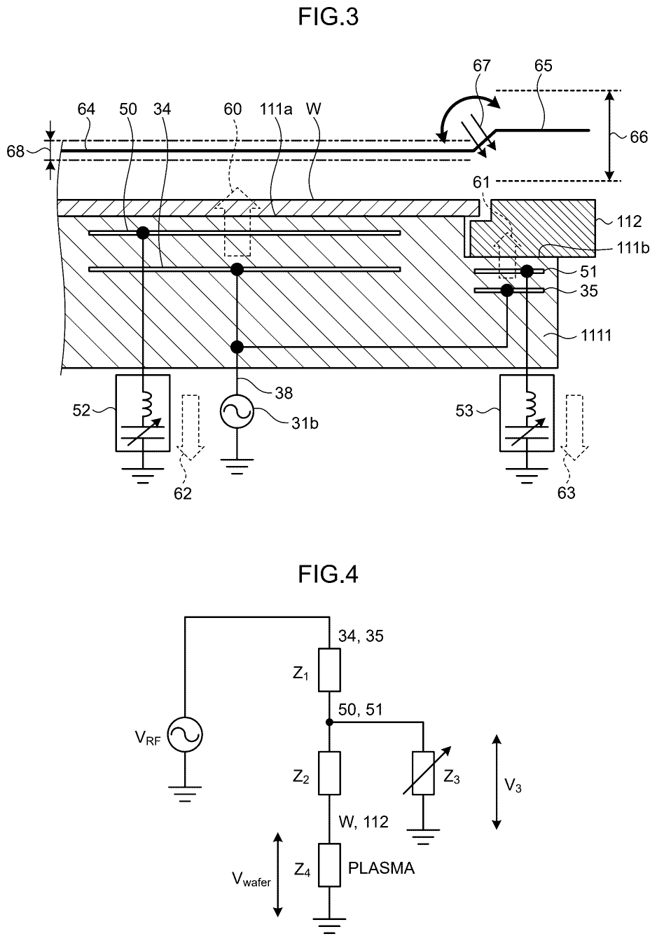

Next, the potential on the substrate support unit 11 will be described with reference to FIG. 3. FIG. 3 is a diagram illustrating an example of the configuration of electrodes in the embodiment. In FIG. 3, it is based on the premise that the bias RF signal is supplied from the second RF generation unit 31b to the first bias electrode 34 and the second bias electrode 35 via the electrical path 38 formed by the base 1110 and the conductive member. The bias DC signal may be supplied from the bias DC generation unit 32a to the first bias electrode 34 and the second bias electrode 35 via the electrical path 38 instead of or together with the bias RF signal. Note that the electrical path 38 is an example of a bias transmission line.

As illustrated in FIG. 3, on the substrate support surface 111a, the bias RF signal supplied from the first bias electrode 34 disposed below the substrate support surface 111a is divided into an RF signal 60 and an RF signal 62. The RF signal 60 is supplied to plasma via the first impedance adjusting electrode 50 and the substrate W. The RF signal 62 flows from the first impedance adjusting electrode 50 to the ground (earth) via the impedance adjusting mechanism 52. In addition, on the ring support surface 111b, the bias RF signal supplied from the second bias electrode 35 disposed below the ring support surface 111b is divided into an RF signal 61 and an RF signal 63. The RF signal 61 is supplied to the plasma via the second impedance adjusting electrode 51 and the ring assembly 112. The RF signal 63 is an RF signal flowing from the second impedance adjusting electrode 51 to the ground (earth) via the impedance adjusting mechanism 53.

At this point, let us presume a case where a potential 64, indicated by a line for presuming a predetermined potential above the substrate W, and a potential 65, indicated by a line for presuming a predetermined potential above the ring assembly 112 have different heights, for example, as illustrated in FIG. 3. In this case, for example, the height of the potential 65 is adjusted within a range 66 by adjusting the impedance adjusting mechanism 53. As a result, in the present embodiment, the tilt angle corresponding to a direction 67 of the electric field can be controlled by the ratio between the potential 64 and the potential 65. Furthermore, for example, by adjusting the impedance adjusting mechanism 52 and the impedance adjusting mechanism 53, the etching rate of the outer peripheral portion of the substrate W can be controlled, and the etching rate of the inner peripheral portion of the substrate W can be controlled. Furthermore, for example, by setting the height of the potential 65 to be lower than the potential 64, even if bias power capable of cleaning the side wall 102 of the plasma processing chamber 10 is supplied, wear of the ring assembly 112 can be suppressed.

In addition, in a case where the impedance adjusting mechanism 52 is adjusted, the height of the potential 64 is adjusted within a range 68. As a result, in the present embodiment, when the etching rate of the outer peripheral portion of the substrate W is controlled, it is possible to suppress a change in the etching rate of the inner peripheral portion of the substrate W at the same time. Furthermore, for example, by setting the height of the potential 64 to be lower than the potential 65, it is possible to suppress the wear of the substrate support surface 111a when, for example, cleaning of the vicinity of the boundary between the substrate support surface 111a and the ring assembly 112 is performed in a state where the substrate W is not held. In FIG. 3, the angle of the direction 67 of the electric field is emphasized for the sake of explanation. In the present embodiment, since the first impedance adjusting electrode 50 and the second impedance adjusting electrode 51 are embedded in the electrostatic chuck 1111, the structure of the plasma processing apparatus 1 can be made compact.

Next, an equivalent circuit of a circuit through which the bias RF signal flows will be described with reference to FIG. 4. FIG. 4 is a diagram illustrating an example of an equivalent circuit of the electrostatic chuck and plasma in the embodiment. In FIG. 4, the bias RF signal supplied to the first bias electrode 34 and the second bias electrode 35 is denoted as V_{RF}. The impedance between the first bias electrode 34 and the second bias electrode 35 and the first impedance adjusting electrode 50 and the second impedance adjusting electrode 51, respectively, is denoted as Z₁. The impedance between the first impedance adjusting electrode 50 and the second impedance adjusting electrode 51 and the substrate W and the ring assembly 112, respectively, is denoted as Z₂. The impedance of the impedance adjusting mechanisms 52 and 53 between the first impedance adjusting electrode 50 and the second impedance adjusting electrode 51, respectively, and the ground (earth) is denoted as Z₃. The impedance of the plasma between each of the substrate W and the ring assembly 112 and the ground is denoted as Z₄.

In this example, a voltage V₃ applied to Z₃ and a voltage V_{wafer} applied to Z₄ can be expressed by the following Equations (1) and (2), respectively. In the Equations (1) to (4), V_{RF} is denoted as V.

$${V}_{3} = \frac{{Z}_{3}}{{Z}_{1} + {Z}_{3}} V \qquad ( 1 )$$

$${V}_{wafer} = \frac{{Z}_{4}}{{Z}_{2} + {Z}_{4}} {V}_{3} \qquad ( 2 )$$

Substituting Equation (1) into Equation (2) gives the voltage V_{wafer} applied to Z₄ expressed by the following Equation (3). Furthermore, dividing the fractional terms in Equation (3) by Z₄ and Z₃ gives the following Equation (4).

$${V}_{wafer} = \frac{{Z}_{4}}{{Z}_{2} + {Z}_{4}} \frac{{Z}_{3}}{{Z}_{1} + {Z}_{3}} V \qquad ( 3 )$$

$${V}_{wafer} = \frac{1}{\frac{{Z}_{2}}{{Z}_{4}} + 1} \frac{1}{\frac{{Z}_{1}}{{Z}_{3}} + 1} V \qquad ( 4 )$$

The fractional term of Equation (4) has a form of f(x)=1/(x+1), and f(x) is a function in which f(x) approaches 1 as x becomes smaller. Therefore, according to Equation (4), the smaller Z₂ is with respect to Z₄, the higher the efficiency with which the potential is transmitted to the plasma. In addition, the smaller Z₁ is with respect to Z₃, the higher the efficiency with which the potential is transmitted to the plasma. In order to reduce Z₂, it is preferable to bring the first impedance adjusting electrode 50 and the second impedance adjusting electrode 51 close to the substrate W and the ring assembly 112, respectively, as much as possible. Similarly, in order to reduce Z₁, it is preferable to bring the first bias electrode 34 and the second bias electrode 35 close to the first impedance adjusting electrode 50 and the second impedance adjusting electrode 51, respectively, as much as possible. As described above, by bringing the first bias electrode 34 and the second bias electrode 35, the first impedance adjusting electrode 50 and the second impedance adjusting electrode 51, and the substrate W and the ring assembly 112, respectively, as close as possible, the sensitivity of potential control can be increased.

### Potential Control Based on Equivalent Circuit

From the equivalent circuit illustrated in FIG. 4, in the potential control in the plasma processing apparatus 1, Z₃ of the impedance adjusting mechanism 52 is controlled such that Z₃ between the first impedance adjusting electrode 50 and the ground is larger than Z₁ between the first bias electrode 34 and the first impedance adjusting electrode 50. That is, the controller 2 controls the potential of the first impedance adjusting electrode 50 by controlling Z₃ of the impedance adjusting mechanism 52.

Similarly, in the potential control in the plasma processing apparatus 1, Z₃ of the impedance adjusting mechanism 53 is controlled such that Z₃ between the second impedance adjusting electrode 51 and the ground is larger than Z₁ between the second bias electrode 35 and the second impedance adjusting electrode 51. That is, the controller 2 controls the potential of the second impedance adjusting electrode 51 by controlling Z₃ of the impedance adjusting mechanism 53.

### Circuit Configuration of Impedance Adjusting Mechanism

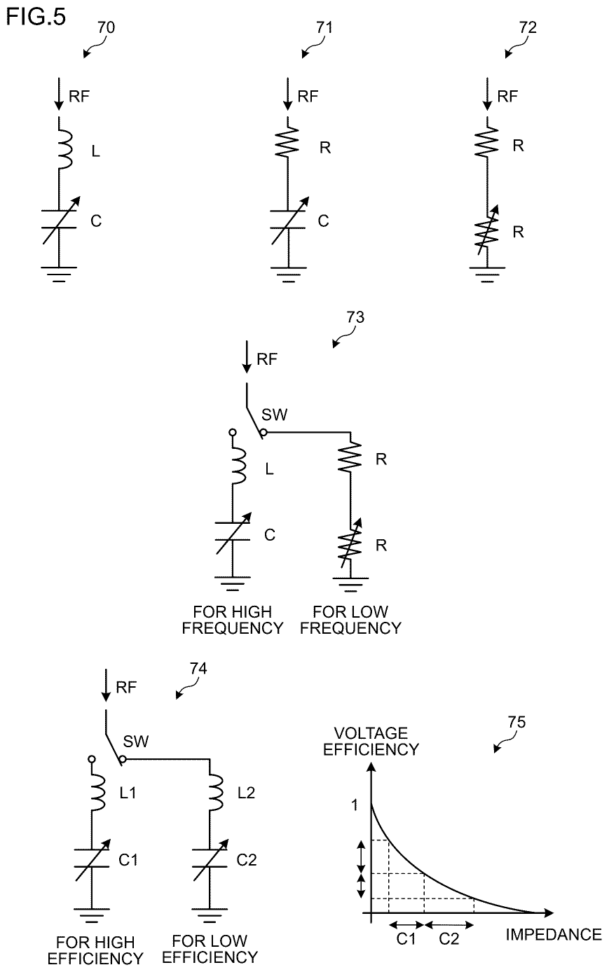

Next, variations of circuit configurations in the impedance adjusting mechanisms 52 and 53 will be described with reference to FIG. 5. FIG. 5 is a diagram illustrating an example of a circuit configuration of an impedance adjusting mechanism in the embodiment. As illustrated in FIG. 5, the impedance adjusting mechanisms 52 and 53 may have various configurations such as circuits 70 to 74. The circuit 70 is an LC series circuit using an inductor and a variable capacitor. The circuit 71 is an RC series circuit using a resistor and a variable capacitor. The circuit 72 is an RR series circuit using a resistor and a variable resistor. The circuit 73 is a circuit in which an LC series circuit for high frequency and an RR series circuit for low frequency can be switched by a switch SW. The circuit 74 is a circuit in which an LC series circuit for high efficiency (inductor L1 and variable capacitor C1) and an LC series circuit for low efficiency (inductor L2 and variable capacitor C2) can be switched by a switch SW. As illustrated in graph 75, the circuit 74 achieves a wider adjustment range by switching the switch SW. Although not illustrated in FIG. 5, the impedance adjusting mechanisms 52 and 53 may have a circuit configuration using a variable inductor.

As described above, in the impedance adjusting mechanisms 52 and 53, a variable resistor, a variable capacitor, a variable inductor, or the like can be used regardless of the type (R, L, or C) of circuit constant to be adjusted. Furthermore, the impedance adjusting mechanisms 52 and 53 may include a combination of one or more variable mechanisms (variable resistor, variable capacitor, variable inductor, etc.) depending on the frequency, the part size, or the adjustment range of the bias RF signal. Since the impedance adjusting mechanisms 52 and 53 do not need to pass a heater current, a variable resistor or a variable capacitor can be used. Furthermore, the impedance adjusting mechanisms 52 and 53 may include at least one of a variable resistor, a variable capacitor, a variable inductor, or a DC power supply. For example, in a case where the bias RF signal has a high frequency, above-described Z₁ and Z₂ have small values, and thus the potential can be controlled more effectively by controlling the potential using a DC power supply. Furthermore, for example, the impedance adjusting mechanisms 52 and 53 may include variable capacitors 54 and 55 as will be described later.

### Concept of Potential in Cleaning Process

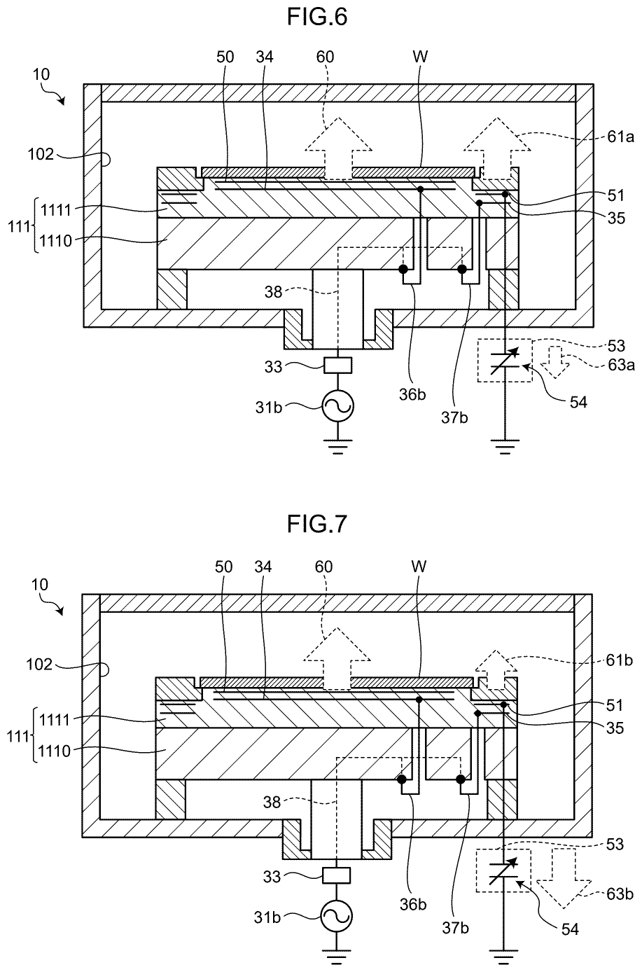

Next, the concept of the potential in the cleaning process of the side wall 102 will be described with reference to FIGS. 6 to 8. Note that in FIGS. 6 to 8, the impedance adjusting mechanism 52 connected with the first impedance adjusting electrode 50 is omitted on the premise that the impedance adjusting mechanism 52 is set to a specific value. FIG. 6 is a diagram illustrating an example of the concept of an RF signal flow in a case where the electrostatic capacitance of a variable capacitor on the ring support surface side is reduced. As illustrated in FIG. 6, for example, during execution of the process, the electrostatic capacitance of the variable capacitor 54 of the impedance adjusting mechanism 53 connected to the second impedance adjusting electrode 51 is controlled to be small in a variable range. In this case, in the bias RF signal supplied from the second bias electrode 35, an RF signal 61a supplied to the plasma flows more than an RF signal 63a flowing to the impedance adjusting mechanism 53 does. In this case, for example, it is based on the premise that the RF signal 61a flows to the same extent as the RF signal 60 on the substrate W side does. That is, in FIG. 6, the bias power hardly escapes to the impedance adjusting mechanism 53, the potential on the ring assembly 112 (edge ring) is high, and for example, the potential on the substrate W and the potential on the ring assembly 112 are controlled to be at about the same level. That is, the plasma sheath thickness on the substrate W and the plasma sheath thickness on the ring assembly 112 are substantially on the same level. Note that, if the cleaning process of the side wall 102 to which large bias power is supplied is performed in this state, the ring assembly 112 is likely to be sputtered, and the wear of the ring assembly 112 increases.

FIG. 7 is a diagram illustrating an example of the concept of an RF signal flow in a case where the electrostatic capacitance of the variable capacitor on the ring support surface side is increased. As illustrated in FIG. 7, for example, when the side wall 102 of the plasma processing chamber 10 is cleaned, the electrostatic capacitance of the variable capacitor 54 of the impedance adjusting mechanism 53 connected to the second impedance adjusting electrode 51 is controlled to be larger than that during execution of the process. In this case, in the bias RF signal supplied from the second bias electrode 35, an RF signal 63b flowing to the impedance adjusting mechanism 53 flows more than an RF signal 61b supplied to the plasma. In this case, for example, the RF signal 61b is less than the RF signal 60 on the substrate W side. That is, in FIG. 7, the bias power easily escapes to the impedance adjusting mechanism 53, and the potential on the ring assembly 112 (edge ring) decreases. Therefore, even if the cleaning process of the side wall 102 to which large bias power is supplied is performed, the ring assembly 112 is hardly sputtered, and the wear of the ring assembly 112 can be suppressed. That is, in the present embodiment, by modifying the potential on the ring assembly 112, the sputtering rate of the ring assembly 112 can be lowered to suppress wear without changing the sputtering rate of other members.

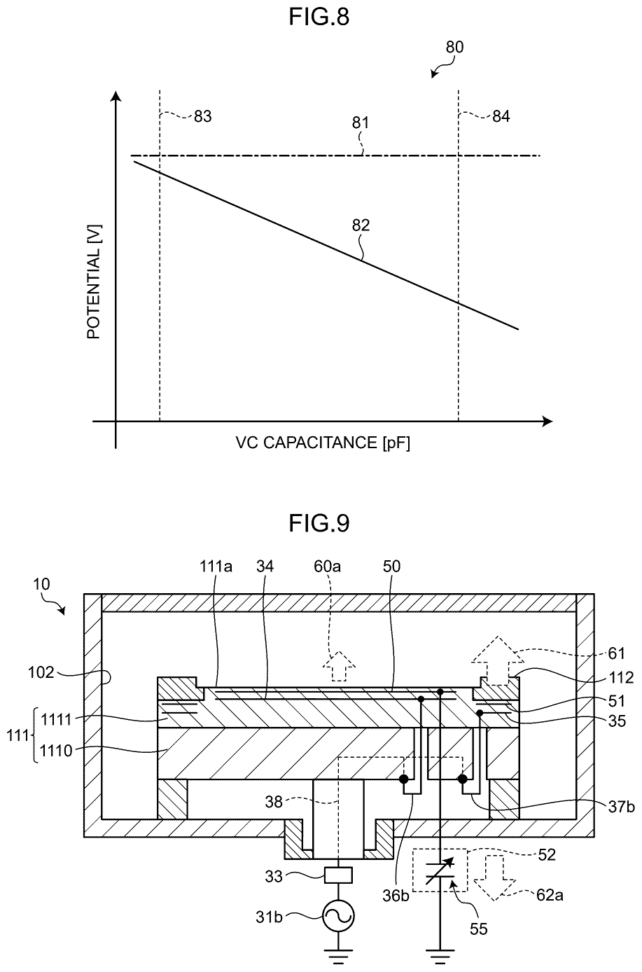

FIG. 8 is a graph illustrating an example of the relationship between the electrostatic capacitance of the variable capacitor on the ring support surface side and the potentials of the substrate and the edge ring in the embodiment. In graph 80 illustrated in FIG. 8, the vertical axis represents the potential [V] of the substrate W and the ring assembly 112, and the horizontal axis represents the electrostatic capacitance of the variable capacitor 54 of the impedance adjusting mechanism 53 as VC capacitance [pF]. In addition, in graph 80, the potential of the substrate W when the electrostatic capacitance of the variable capacitor 54 of the impedance adjusting mechanism 53 is changed is represented as a line 81, and the potential of the ring assembly 112 is represented as a line 82. Furthermore, in graph 80, the electrostatic capacitance 83 of the variable capacitor 54 at the time of executing the process and the electrostatic capacitance 84 of the variable capacitor 54 at the time of performing the cleaning process are each indicated by a dotted line.

At the time of execution of the process, the variable capacitor 54 is controlled to have the electrostatic capacitance 83, and as indicated by the lines 81 and 82, the potential of the ring assembly 112 becomes substantially on the same level as the potential of the substrate W. That is, at the time of executing the process, the variable capacitor 54 is controlled such that the plasma sheath thickness on the substrate W and the ring assembly 112 is constant. On the other hand, during the cleaning process, the variable capacitor 54 is controlled to have the electrostatic capacitance 84, and as indicated by the lines 81 and 82, the potential of the ring assembly 112 becomes lower than the potential of the substrate W. That is, by controlling the variable capacitor 54 to have the electrostatic capacitance 84, it is possible to suppress the wear of the ring assembly 112 during the cleaning process. Since the impedance adjusting mechanism 52 is set to a specific value, the potential of the substrate W indicated by the line 81 does not change even when the electrostatic capacitance of the variable capacitor 54 is changed. In addition, the electrostatic capacitance of the variable capacitor 54 may be adjusted to a value between the electrostatic capacitance 83 and the electrostatic capacitance 84, for example, depending on the member in the plasma processing chamber 10 to be cleaned.

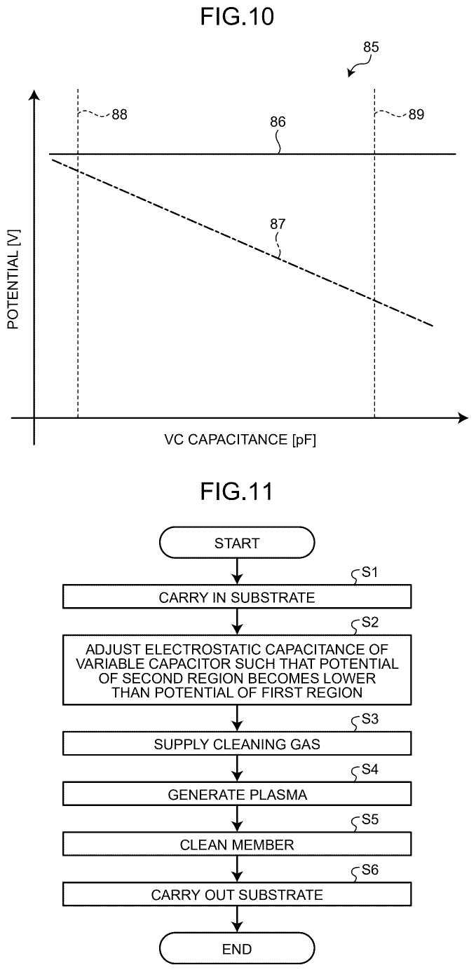

Next, the concept of the potential in the cleaning process in the vicinity of the boundary between the substrate support surface 111a and the ring assembly 112 will be described with reference to FIGS. 9 and 10. Note that in FIGS. 9 and 10, the impedance adjusting mechanism 53 connected to the second impedance adjusting electrode 51 is omitted on the premise that the impedance adjusting mechanism 53 is set to a specific value. FIG. 9 is a diagram illustrating an example of the concept of an RF signal flow in a case where the electrostatic capacitance of the variable capacitor on the substrate support surface side is increased. Note that FIG. 9 illustrates a state of the waferless cleaning in which no substrate W is placed on the substrate support surface 111a in order to clean the vicinity of the boundary between the substrate support surface 111a and the ring assembly 112. For example, organic deposits (for example, deposits containing carbon) may adhere to the vicinity of the boundary between the substrate support surface 111a and the ring assembly 112. The organic deposits can be cleaned with lower ion energy than that for deposits containing metal that adhere to the side wall 102.

In FIG. 9, for example, a cleaning process for the vicinity of the boundary between the substrate support surface 111a and the ring assembly 112 will be studied. In the cleaning process, the electrostatic capacitance of the variable capacitor 55 of the impedance adjusting mechanism 52 connected to the first impedance adjusting electrode 50 is controlled to be larger than that at the time of executing the process. In this case, in the bias RF signal supplied from the first bias electrode 34, an RF signal 62a flowing to the impedance adjusting mechanism 52 flows more than an RF signal 60a supplied to the plasma. In this case, for example, the RF signal 60a is less than the RF signal 61 on the ring assembly 112 side. That is, in FIG. 9, the bias power easily escapes to the impedance adjusting mechanism 52, and the potential on the substrate support surface 111a is lower than the potential on the ring assembly 112. Therefore, it is possible to suppress the wear of the substrate support surface 111a when performing cleaning in the vicinity of the boundary between the substrate support surface 111a and the ring assembly 112.

FIG. 10 is a graph illustrating an example of the relationship between the electrostatic capacitance of the variable capacitor on the substrate support surface side and the potentials of the substrate and the edge ring in the embodiment. In graph 85 illustrated in FIG. 10, the vertical axis represents the potential [V] of the substrate support surface 111a and the ring assembly 112, and the horizontal axis represents the electrostatic capacitance of the variable capacitor 55 of the impedance adjusting mechanism 52 as VC capacitance [pF]. In addition, in graph 85, the potential of the ring assembly 112 when the electrostatic capacitance of the variable capacitor 55 of the impedance adjusting mechanism 52 is changed is represented as a line 86, and the potential of the substrate support surface 111a is represented as a line 87. Furthermore, in graph 85, the electrostatic capacitance 88 of the variable capacitor 55 at the time of executing the process and the electrostatic capacitance 89 of the variable capacitor 55 at the time of performing the cleaning process are each indicated by a dotted line.

At the time of execution of the process, the variable capacitor 55 is controlled to have the electrostatic capacitance 88, and as indicated by the lines 86 and 87, the potential of the substrate W (substantially equal to the potential of the substrate support surface 111a) becomes substantially on the same level as the potential of the ring assembly 112. That is, at the time of executing the process, the variable capacitor 55 is controlled such that the plasma sheath thickness on the substrate W and the ring assembly 112 is constant. On the other hand, during the cleaning process, the variable capacitor 55 is controlled to have the electrostatic capacitance 89, and as indicated by the lines 86 and 87, the potential of the substrate support surface 111a becomes lower than the potential of the ring assembly 112. That is, by controlling the variable capacitor 55 to have the electrostatic capacitance 89, it is possible to suppress the wear of the substrate support surface 111a during the cleaning process. Since the impedance adjusting mechanism 53 is set to a specific value, the potential of the ring assembly 112 indicated by the line 86 does not change even when the electrostatic capacitance of the variable capacitor 55 is changed. In addition, the electrostatic capacitance of the variable capacitor 55 may be adjusted to a value between the electrostatic capacitance 88 and the electrostatic capacitance 89, for example, depending on the member in the plasma processing chamber 10 to be cleaned.

### Cleaning Method

Next, a cleaning method in the plasma processing chamber 10 in the embodiment will be described. FIG. 11 is a flowchart illustrating an example of the cleaning process in the embodiment. In FIG. 11, a case where the substrate W for cleaning is carried in and the side wall 102 of the plasma processing chamber 10 is cleaned, for example, will be described as an example.

The controller 2 opens a carrying-in/out port (not illustrated) by controlling a gate valve (not illustrated). When the carrying-in/out port is opened, the substrate W is carried into the plasma processing space 10s of the plasma processing chamber 10 via the carrying-in/out port and is adsorbed and held by the substrate support unit 11. That is, the controller 2 controls the plasma processing apparatus 1 in such a manner as to carry in the substrate W into the plasma processing chamber 10 (step S1). Note that the controller 2 may be a control device of the entire substrate processing system (not illustrated) including the plasma processing apparatus 1 and a transfer device of a transfer chamber (not illustrated) adjacent to the plasma processing chamber 10. The controller 2 closes the carrying-in/out port by controlling the gate valve.

The controller 2 adjusts the electrostatic capacitance of the variable capacitor 54 connected to the second impedance adjusting electrode 51 to be larger than that at the time of executing the process by controlling the impedance adjusting mechanism 53. That is, the controller 2 controls the impedance adjusting mechanism 53 to adjust the electrostatic capacitance of the variable capacitor 54 such that the potential of the second region (ring assembly 112) becomes lower than the potential of the first region (substrate W) (step S2).

The controller 2 controls the exhaust system 40 connected to the gas discharge port 10e to reduce the pressure in the plasma processing chamber 10 to a predetermined pressure. The controller 2 controls the gas supply unit 20 to supply the cleaning gas (plasma generation gas) from the plurality of gas introduction ports 13c to the plasma processing chamber 10 (step S3). The controller 2 controls the power supply 30 to ignite plasma with predetermined power. That is, the controller 2 controls the power supply 30 to supply high-frequency power for plasma generation into the plasma processing chamber 10 to generate plasma from the cleaning gas (step S4). The controller 2 controls the power supply 30 to supply bias power into the plasma processing chamber 10 to clean members (for example, side wall 102) in the plasma processing chamber 10 (step S5). Note that the controller 2 may change the member to be cleaned by controlling the impedance adjusting mechanism 53 during cleaning. That is, the controller 2 may adjust the potential of the impedance adjusting electrode (second impedance adjusting electrode 51) depending on the member in the plasma processing chamber 10 to be cleaned. That is, the order of steps S2 to S5 may be modified or combined as long as there is no contradiction.

When cleaning is performed for a predetermined time, the controller 2 controls the power supply 30 to stop the RF signal and stop generation of plasma. The controller 2 also opens the carrying-in/out port by controlling the gate valve. The controller 2 controls the plasma processing apparatus 1 in such a manner as to lift the substrate W with a lifter (not illustrated). When the carrying-in/out port is opened, the substrate W is carried out from the plasma processing chamber 10 by an arm of a transfer chamber (not illustrated) via the carrying-in/out port. That is, the controller 2 controls the plasma processing apparatus 1 to carry out the substrate W from the plasma processing chamber 10 (step S6). As described above, since the controller 2 performs cleaning after adjusting the electrostatic capacitance of the variable capacitor 54 such that the potential of the ring assembly 112 becomes lower than the potential of the substrate W, it is possible to suppress the wear of members in the chamber while supplying large bias power. That is, in the present embodiment, the wear of the ring assembly 112 (edge ring) can be suppressed while supplying large bias power to clean the side wall 102 of the plasma processing chamber 10. In the present embodiment, the replacement interval of members in the plasma processing chamber 10 can be extended. Furthermore, in the embodiment, since the step of adjusting the electrostatic capacitance of the variable capacitor 54 is added to existing cleaning conditions, the existing cleaning conditions can be repurposed. In addition, the throughput of cleaning can be improved as compared with a method of forming a protective film on a member to be protected from wear.

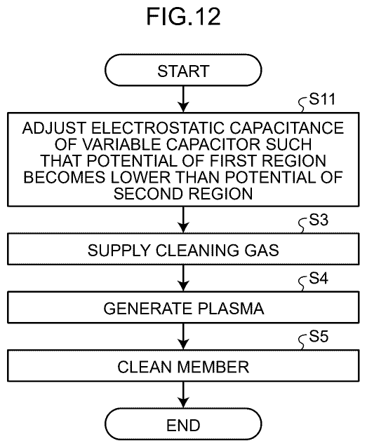

FIG. 12 is a flowchart illustrating an example of a waferless cleaning process according to the embodiment. Note that in FIG. 12, for example, a case where the vicinity of the boundary between the first region (substrate support surface 111a) and the second region (ring assembly 112) is cleaned without carrying in the substrate W for cleaning will be described as an example. In the following description, steps S3 to S5 of a waferless cleaning process in FIG. 12 are similar to those of the cleaning process in FIG. 11, and thus description thereof will be omitted.

As illustrated in FIG. 12, the controller 2 executes the following process instead of the process of steps S1 and S2. The controller 2 adjusts the electrostatic capacitance of the variable capacitor 55 connected to the first impedance adjusting electrode 50 to be larger than that at the time of executing the process by controlling the impedance adjusting mechanism 52. That is, the controller 2 controls the impedance adjusting mechanism 52 to adjust the electrostatic capacitance of the variable capacitor 55 such that the potential of the first region (substrate support surface 111a) becomes lower than the potential of the second region (ring assembly 112) (step S1l). After adjusting the electrostatic capacitance of variable capacitor 55, the controller 2 proceeds to step S3.

Subsequently to step S5, after cleaning for a predetermined time is performed, the controller 2 controls the power supply 30 to stop the RF signal and stop the generation of plasma, thereby ending the waferless cleaning process. Note that in steps S11 and S3 to S5, the potential of the impedance adjusting electrode (first impedance adjusting electrode 50) may be adjusted depending on the member in the plasma processing chamber 10 to be cleaned. That is, the order of steps S11 and S3 to S5 may be modified or combined as long as there is no contradiction. As described above, since the controller 2 performs cleaning after adjusting the electrostatic capacitance of the variable capacitor 55 such that the potential of the first region (substrate support surface 111a) becomes lower than the potential of the second region (ring assembly 112), wear of the first region (substrate support surface 111a) can be suppressed.

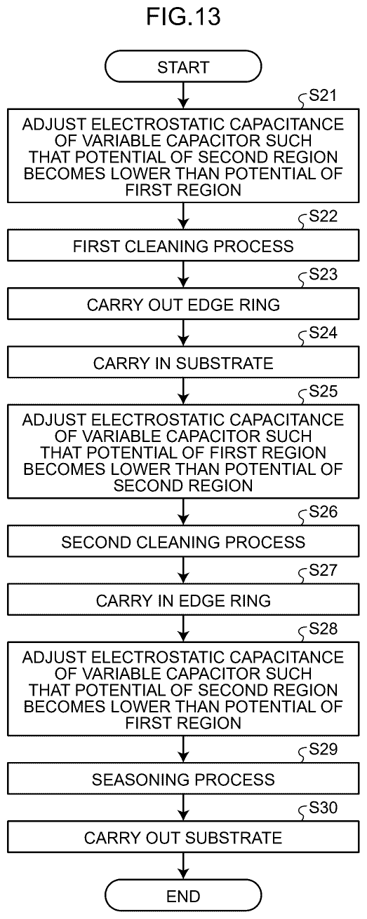

FIG. 13 is a flowchart illustrating an example of an edge ring replacement process in the embodiment. In FIG. 13, the cleaning process and a seasoning process at the time of replacing the edge ring will be described as an example.

As illustrated in FIG. 13, the controller 2 adjusts the electrostatic capacitance of the variable capacitor 54 connected to the second impedance adjusting electrode 51 to be larger than that at the time of executing the process by controlling the impedance adjusting mechanism 53. That is, the controller 2 controls the impedance adjusting mechanism 53 to adjust the electrostatic capacitance of the variable capacitor 54 such that the potential of the second region (ring assembly 112) becomes lower than the potential of the first region (substrate support surface 111a) (step S21).

The controller 2 executes a first cleaning process (step S22). That is, similarly to steps S3 to S5 of the cleaning process of FIG. 11, the controller 2 controls the exhaust system 40 connected to the gas discharge port 10e to reduce the pressure in the plasma processing chamber 10 to a predetermined pressure. The controller 2 controls the gas supply unit 20 to supply the cleaning gas (plasma generation gas) from the plurality of gas introduction ports 13c to the plasma processing chamber 10. The controller 2 controls the power supply 30 to ignite plasma with predetermined power. That is, the controller 2 controls the power supply 30 to supply high-frequency power for plasma generation into the plasma processing chamber 10 to generate plasma from the cleaning gas. The controller 2 controls the power supply 30 to supply bias power into the plasma processing chamber 10 to clean members in the plasma processing chamber 10. That is, the first cleaning process is an example of a process of performing waferless cleaning of the substrate support unit 11. Note that the first cleaning process is an example of a process of performing first plasma cleaning.

When cleaning is performed for a predetermined time, the controller 2 controls the power supply 30 to stop the RF signal and stop generation of plasma. The controller 2 also opens the carrying-in/out port by controlling the gate valve. The controller 2 controls the plasma processing apparatus 1 in such a manner as to lift the edge ring of the ring assembly 112 with a lifter (not illustrated). When the carrying-in/out port is opened, the edge ring is carried out from the plasma processing chamber 10 by an arm of a transfer chamber (not illustrated) via the carrying-in/out port. That is, the controller 2 controls the plasma processing apparatus 1 to carry out the edge ring from the plasma processing chamber 10 (step S23).

When the carrying-in/out port is opened, the substrate W is carried into the plasma processing space 10s of the plasma processing chamber 10 via the carrying-in/out port and is adsorbed and held by the substrate support unit 11. That is, the controller 2 controls the plasma processing apparatus 1 in such a manner as to carry in the substrate W into the plasma processing chamber 10 (step S24). The controller 2 closes the carrying-in/out port by controlling the gate valve.

The controller 2 adjusts the electrostatic capacitance of the variable capacitor 55 connected to the first impedance adjusting electrode 50 to be larger than that at the time of executing the process by controlling the impedance adjusting mechanism 52. That is, the controller 2 controls the impedance adjusting mechanism 52 to adjust the electrostatic capacitance of the variable capacitor 55 such that the potential of the first region (substrate support surface 111a) becomes lower than the potential of the second region (ring support surface 111b) (step S25).

The controller 2 executes a second cleaning process (step S26). That is, similarly to steps S3 to S5 of the cleaning process of FIG. 11, the controller 2 controls the exhaust system 40 connected to the gas discharge port 10e to reduce the pressure in the plasma processing chamber 10 to a predetermined pressure. The controller 2 controls the gas supply unit 20 to supply the cleaning gas (plasma generation gas) from the plurality of gas introduction ports 13c to the plasma processing chamber 10. The controller 2 controls the power supply 30 to ignite plasma with predetermined power. That is, the controller 2 controls the power supply 30 to supply high-frequency power for plasma generation into the plasma processing chamber 10 to generate plasma from the cleaning gas. The controller 2 controls the power supply 30 to supply bias power into the plasma processing chamber 10 to clean the second region (ring support surface 111b). That is, the second cleaning process is an example of a process of cleaning the second region (ring support surface 111b) in a state where the substrate W for cleaning is supported by the first region (substrate support surface 111a). Note that the second cleaning process is an example of a process of performing second plasma cleaning.

When cleaning is performed for a predetermined time, the controller 2 controls the power supply 30 to stop the RF signal and stop generation of plasma. The controller 2 also opens the carrying-in/out port by controlling the gate valve. When the carrying-in/out port is opened, an unused edge ring is carried into the plasma processing space 10s of the plasma processing chamber 10 via the carrying-in/out port and is adsorbed and held by the substrate support unit 11. That is, the controller 2 controls the plasma processing apparatus 1 such that the unused edge ring of the ring assembly 112 is carried into the plasma processing chamber 10 (step S27). The controller 2 closes the carrying-in/out port by controlling the gate valve.

The controller 2 adjusts the electrostatic capacitance of the variable capacitor 54 connected to the second impedance adjusting electrode 51 to be larger than that at the time of executing the process by controlling the impedance adjusting mechanism 53. That is, the controller 2 controls the impedance adjusting mechanism 53 to adjust the electrostatic capacitance of the variable capacitor 54 such that the potential of the second region (ring assembly 112) becomes lower than the potential of the first region (substrate W) (step S28).

The controller 2 executes a seasoning process (step S29). That is, the controller 2 controls the exhaust system 40 connected to the gas discharge port 10e to reduce the pressure in the plasma processing chamber 10 to a predetermined pressure. The controller 2 controls the gas supply unit 20 to supply the plasma generation gas from the plurality of gas introduction ports 13c to the plasma processing chamber 10. The controller 2 controls the power supply 30 to ignite plasma with predetermined power. That is, the controller 2 controls the power supply 30 to supply high-frequency power for plasma generation into the plasma processing chamber 10 to generate plasma from the plasma generation gas. The controller 2 performs the seasoning process using the generated plasma. The seasoning process is for stabilizing the temperature in the plasma processing chamber 10 and the state of the deposit by performing a predetermined plasma process. That is, the seasoning process is an example of plasma processing performed in a state where the substrate W for cleaning is supported by the first region (substrate support surface 111a) and an unused edge ring of the ring assembly 112 is supported by the second region (ring support surface 111b).

When the seasoning process is performed for a predetermined time, the controller 2 controls the power supply 30 to stop the RF signal and stop generation of plasma. The controller 2 also opens the carrying-in/out port by controlling the gate valve. The controller 2 controls the plasma processing apparatus 1 in such a manner as to lift the substrate W with a lifter (not illustrated). When the carrying-in/out port is opened, the substrate W is carried out from the plasma processing chamber 10 by an arm of a transfer chamber (not illustrated) via the carrying-in/out port. That is, the controller 2 controls the plasma processing apparatus 1 to carry out the substrate W from the plasma processing chamber 10 (step S30). After the seasoning process, the controller 2 may carry in a substrate for quality control and perform a predetermined process on the substrate for quality control. As a result, it is possible to confirm whether or not the state of the plasma processing chamber 10 is normal.

As described above, in the first cleaning process, the second cleaning process, and the seasoning process, the controller 2 adjusts the electrostatic capacitance of at least one of the variable capacitors 54 and 55 and then performs the plasma processing, and thus the edge ring can be replaced while suppressing the wear of members in the chamber.

Rephrasing the above-described cleaning process, the controller 2 controls the plasma processing apparatus 1 in such a manner as to support the substrate W on the substrate support unit 11 disposed in the plasma processing chamber 10, the substrate support unit 11 including the first region that supports the substrate W and the second region that supports the edge ring (ring assembly 112). In addition, the controller 2 controls the impedance adjusting mechanism 53 connected to the impedance adjusting electrode (second impedance adjusting electrode 51) provided in the second region to adjust the potential of the impedance adjusting electrode (second impedance adjusting electrode 51) such that the potential of the second region becomes lower than the potential of the first region. In addition, the controller 2 controls the gas supply unit 20 to supply the cleaning gas into the plasma processing chamber 10. The controller 2 also controls the first RF generation unit 31a (source power supply) to supply the source RF signal (high-frequency power) into the plasma processing chamber 10 to generate plasma from the cleaning gas. In addition, the controller 2 controls at least one of the second RF generation unit 31b and the bias DC generation unit 32a (bias power supply) in such a manner that at least one of the bias RF signal and the bias DC signal (bias power) is supplied into the plasma processing chamber 10 to clean a member in the plasma processing chamber 10 (for example, side wall 102).

Furthermore, in a case where waferless cleaning is performed in the vicinity of the boundary between the first region and the second region, the controller 2 controls each unit as follows. The controller 2 controls the impedance adjusting mechanism 52 connected to the impedance adjusting electrode (first impedance adjusting electrode 50) provided in the first region to adjust the potential of the impedance adjusting electrode (first impedance adjusting electrode 50) such that the potential of the first region becomes lower than the potential of the second region. In addition, the controller 2 controls the gas supply unit 20 to supply the cleaning gas into the plasma processing chamber 10. The controller 2 also controls the first RF generation unit 31a (source power supply) to supply the source RF signal (high-frequency power) into the plasma processing chamber 10 to generate plasma from the cleaning gas. In addition, the controller 2 controls at least one of the second RF generation unit 31b and the bias DC generation unit 32a (bias power supply) in such a manner that at least one of the bias RF signal and the bias DC signal (bias power) is supplied into the plasma processing chamber 10 to clean a member in the plasma processing chamber 10 (for example, the vicinity of the boundary between the substrate support surface 111a and the ring assembly 112).

In the edge ring replacement process, the controller 2 controls each unit as follows. In the case of performing the waferless cleaning on the first region, the controller 2 controls the impedance adjusting mechanism 53 connected to the impedance adjusting electrode (second impedance adjusting electrode 51) provided in the second region to adjust the potential of the impedance adjusting electrode (second impedance adjusting electrode 51) such that the potential of the second region becomes lower than the potential of the first region. In the case of performing cleaning on the ring support surface 111b, the controller 2 controls the impedance adjusting mechanism 52 connected to the impedance adjusting electrode (first impedance adjusting electrode 50) provided in the first region to adjust the potential of the impedance adjusting electrode (first impedance adjusting electrode 50) such that the potential of the first region becomes lower than the potential of the second region. In addition, in the case of performing the seasoning, the controller 2 controls the impedance adjusting mechanism 53 connected to the impedance adjusting electrode (second impedance adjusting electrode 51) provided in the second region to adjust the potential of the impedance adjusting electrode (second impedance adjusting electrode 51) such that the potential of the second region becomes lower than the potential of the first region.

In the above embodiment, the first impedance adjusting electrode 50 and the second impedance adjusting electrode 51 are provided below the substrate support surface 111a and the ring support surface 111b, respectively; however, it is not limited thereto. For example, one of the first impedance adjusting electrode 50 or the second impedance adjusting electrode 51 may be provided.

As described above, according to the present embodiment, the cleaning method is for the plasma processing apparatus 1 and includes: the step of supporting the substrate W on the substrate support (substrate support unit 11) disposed in the chamber (plasma processing chamber 10) and including the first region (substrate support surface 111a) that supports the substrate W and the second region (ring support surface 111b) that supports the edge ring (ring assembly 112); the step of adjusting the potential of the impedance adjusting electrode such that the potential of the second region becomes lower than the potential of the first region by controlling the impedance adjusting mechanism (variable capacitor 54) connected to the impedance adjusting electrode (second impedance adjusting electrode 51) provided in the second region; the step of supplying the cleaning gas into the chamber; the step of generating plasma from the cleaning gas by supplying high-frequency power for plasma generation into the chamber; and the step of cleaning a member in the chamber by supplying bias power into the chamber. As a result, it is possible to suppress wear of members in the chamber such as the edge ring while supplying large bias power.

In addition, according to the present embodiment, the bias power is capable of cleaning the side wall 102 in the chamber. As a result, deposits including metal adhering to the side wall 102 can be removed.

According to the present embodiment, in the cleaning process, the potential of at least one of the first impedance adjusting electrode 50 or the second impedance adjusting electrode 51 is adjusted depending on the member in the chamber to be cleaned. As a result, the member to be cleaned can be cleaned.

Furthermore, according to the present embodiment, the bias power includes one or more of a high frequency signal and a pulsed DC signal. As a result, it is possible to suppress wear of members in the chamber while supplying large bias power regardless of the waveform of the bias power supply.

According to the present embodiment, the impedance adjusting mechanism includes at least one of a variable resistor, a variable capacitor (variable capacitors 54 and 55), and a variable inductor. As a result, the potential of the impedance adjusting electrode can be adjusted.

Furthermore, according to the present embodiment, the cleaning method is for the plasma processing apparatus 1 and includes: in the substrate support (substrate support unit 11) disposed in the chamber (plasma processing chamber 10), the substrate support including the first region (substrate support surface 111a) that supports the substrate W and the second region (ring support surface 111b) that supports the edge ring (ring assembly 112), the step of adjusting the potential of the impedance adjusting electrode such that the potential of the first region becomes lower than the potential of the second region by controlling the impedance adjusting mechanism (variable capacitor 55) connected to the impedance adjusting electrode (first impedance adjusting electrode 50) provided in the first region; the step of supplying the cleaning gas into the chamber; the step of generating plasma from the cleaning gas by supplying high-frequency power for plasma generation into the chamber; and the step of cleaning a member in the chamber by supplying bias power into the chamber. As a result, it is possible to suppress wear of the substrate support surface 111a when cleaning (waferless cleaning) in the vicinity of the boundary between the substrate support surface 111a and the ring assembly 112 is performed.

Furthermore, according to the present embodiment, the cleaning method is for the plasma processing apparatus 1 and includes: in the substrate support (substrate support unit 11) disposed in the chamber (plasma processing chamber 10), the substrate support including the first region (substrate support surface 111a) that supports the substrate W and the second region (ring support surface 111b) that supports the edge ring (ring assembly 112), the step of adjusting the potential of the impedance adjusting electrode such that the potential of the second region becomes lower than the potential of the first region by controlling the impedance adjusting mechanism (variable capacitor 54) connected to the impedance adjusting electrode (second impedance adjusting electrode 51) provided in the second region; the step of supplying the cleaning gas into the chamber; the step of generating plasma from the cleaning gas by supplying high-frequency power for plasma generation into the chamber; and the step of cleaning a member in the chamber by supplying bias power into the chamber. As a result, in cleaning in the edge ring replacement process, it is possible to suppress wear of the edge ring while supplying large bias power.

Furthermore, according to the present embodiment, the cleaning method further includes: the step of carrying out the edge ring from the chamber; the step of supporting the substrate W in the first region; and the step of adjusting the potential of the impedance adjusting electrode such that the potential of the first region becomes lower than the potential of the second region by controlling the impedance adjusting mechanism (variable capacitor 55) connected to the impedance adjusting electrode (first impedance adjusting electrode 50) provided in the first region. As a result, the ring support surface 111b can be cleaned in the edge ring replacement process.

Furthermore, according to the present embodiment, the cleaning method further includes the step of supporting the edge ring in the second region; and the step of adjusting the potential of the impedance adjusting electrode such that the potential of the second region becomes lower than the potential of the first region by controlling the impedance adjusting mechanism (variable capacitor 54) connected to the impedance adjusting electrode (second impedance adjusting electrode 51) provided in the second region. As a result, in the edge ring replacement process, the plasma processing chamber 10 including the replaced edge ring can be subjected to the seasoning process.

In addition, according to the present embodiment, the bias power is power capable of cleaning the first region. As a result, wear of other members in the plasma processing chamber 10 can be suppressed.

In addition, according to the present embodiment, the plasma processing apparatus 1 includes the chamber (plasma processing chamber 10), the plasma generation unit (RF power supply 31), the substrate support unit 11, the bias power supply (DC power supply 32), the impedance adjusting electrode, the impedance adjusting mechanism, and the controller 2. The plasma generation unit generates plasma in the chamber. The substrate support unit 11 is disposed in the chamber, and includes the base 1110, the electrostatic chuck 1111, the first bias electrode 34, the second bias electrode 35, and the edge ring (ring assembly 112). The electrostatic chuck 1111 is disposed on the base 1110, and the electrostatic chuck 1111 includes the first region having the substrate support surface 111a and the second region disposed outside the first region and having the ring support surface 111b. The first bias electrode 34 is disposed in the first region. The second bias electrode 35 is disposed in the second region. The edge ring is disposed on the ring support surface 111b. The bias power supply is electrically connected to the first bias electrode 34 and the second bias electrode 35 via the bias transmission line, and supplies a bias signal to the first bias electrode 34 and the second bias electrode 35. The impedance adjusting electrode (for example, the first impedance adjusting electrode 50 and the second impedance adjusting electrode 51) is provided in at least one of the first region or the second region. The impedance adjusting mechanism (for example, the impedance adjusting mechanisms 52 and 53) is connected to the impedance adjusting electrode. In addition, the impedance adjusting electrode is grounded via the impedance adjusting mechanism. The controller 2 executes: (a) plasma processing on the substrate on the substrate support unit 11 in the chamber; and (b) plasma-cleaning on the inside of the chamber by controlling the impedance adjusting mechanism such that the potential in a region in which a member in the chamber to be cleaned is disposed becomes higher than a potential in (a), the region being one of the first region or the second region. As a result, it is possible to suppress wear of members in the chamber while supplying large bias power.

In addition, according to the present embodiment, the impedance adjusting electrode (first impedance adjusting electrode 50) is provided in such a manner as to be parallel to the first bias electrode 34 at least in the first region. Furthermore, (b) includes first plasma cleaning performed in a state where the substrate W is supported on the substrate support unit 11. In the first plasma cleaning, the controller 2 controls the impedance adjusting mechanism 52 such that the potential of the first region becomes lower than the potential of the second region. As a result, the potential on the substrate support surface 111a side can be controlled. In addition, the edge ring can be cleaned.

In addition, according to the present embodiment, the impedance adjusting electrode (second impedance adjusting electrode 51) is provided in such a manner as to be parallel to the second bias electrode 35 at least in the second region. Furthermore, (b) includes second plasma cleaning performed in a state where the substrate W is not supported on the substrate support unit 11. In the second plasma cleaning, the controller 2 controls the impedance adjusting mechanism 53 such that the potential of the second region becomes lower than the potential of the first region. As a result, the potential on the edge ring (ring assembly 112) side can be controlled.

The embodiments disclosed herein are to be considered in all respects as illustrative and not restrictive. The above embodiments may be omitted, replaced, or modified in various forms without departing from the scope and the gist of the appended claims.

Note that the present disclosure can also have the following configurations.

(1)

A cleaning method for a plasma processing apparatus, the method comprising:
a step of supporting a substrate on a substrate support disposed in a chamber, the substrate support comprising a first region supporting the substrate and a second region supporting an edge ring;
a step of adjusting a potential of an impedance adjusting electrode such that a potential of the second region becomes lower than a potential of the first region by controlling an impedance adjuster connected to the impedance adjusting electrode provided in the second region;
a step of supplying a cleaning gas into the chamber;
a step of generating plasma from the cleaning gas by supplying high-frequency power for plasma generation into the chamber; and
a step of cleaning a member in the chamber by supplying bias power into the chamber.
   (2)

The cleaning method according to (1), wherein
the bias power causes cleaning of a side wall in the chamber.
   (3)

The cleaning method according to (1) or (2), wherein
during the step of cleaning, the potential of the impedance adjusting electrode is adjusted depending on the member in the chamber to be cleaned.
   (4)

The cleaning method according to any one of (1) to (3), wherein
the bias power includes one or more of a high frequency signal and a pulsed DC signal.
   (5)

The cleaning method according to any one of (1) to (4), wherein
the impedance adjuster includes at least one of a variable resistor, a variable capacitor, and a variable inductor.
   (6)

A cleaning method for a plasma processing apparatus, the method comprising:
in a substrate support disposed in a chamber, the substrate support comprising a first region supporting a substrate and a second region supporting an edge ring, a step of adjusting a potential of an impedance adjusting electrode to cause a potential of the first region to become lower than a potential of the second region by controlling an impedance adjuster connected to the impedance adjusting electrode provided in the first region;
a step of supplying a cleaning gas into the chamber;
a step of generating plasma from the cleaning gas by supplying high-frequency power for plasma generation into the chamber; and
a step of cleaning a member in the chamber by supplying bias power into the chamber.
   (7)

A cleaning method for a plasma processing apparatus, the method comprising:
in a substrate support disposed in a chamber, the substrate support comprising a first region supporting a substrate and a second region supporting an edge ring, a step of adjusting a potential of an impedance adjusting electrode to cause a potential of the second region to become lower than a potential of the first region, the step of adjusting the potential of the impedance adjusting electrode being performed by controlling an impedance adjuster connected to the impedance adjusting electrode provided in the second region;
a step of supplying a cleaning gas into the chamber;
a step of generating plasma from the cleaning gas by supplying high-frequency power for plasma generation into the chamber; and
a step of cleaning a member in the chamber by supplying bias power into the chamber.
   (8)

The cleaning method according to (7), further comprising, after the step of cleaning the member:
a step of carrying out the edge ring from the chamber;
a step of supporting the substrate in the first region; and
a step of adjusting the potential of the impedance adjusting electrode to cause the potential of the first region to become lower than the potential of the second region by controlling the impedance adjuster connected to the impedance adjusting electrode provided in the first region.
   (9)

The cleaning method according to (8), further comprising, after adjusting the potential of the impedance adjusting electrode to cause the potential of the first region to become lower than the potential of the second region:
a step of supporting the edge ring in the second region; and
a step of adjusting the potential of the impedance adjusting electrode to cause the potential of the second region to become lower than the potential of the first region by controlling the impedance adjuster connected to the impedance adjusting electrode provided in the second region.
   (9A) The cleaning method according to (9), further comprising executing a seasoning process by controlling a gas supply to supply plasma generation gas from a plurality of gas introduction ports to the chamber and controlling a power supply to ignite plasma in the chamber.
   (10)

The cleaning method according to any one of (7) to (9), wherein
the bias power causes cleaning of the first region.
   (11)

The cleaning method according to any one of (7) to (10), wherein
in the step of cleaning, the potential of the impedance adjusting electrode is adjusted depending on the member in the chamber to be cleaned.
   (12)

The cleaning method according to any one of (7) to (11), wherein
the bias power includes one or more of a high frequency signal and a pulsed DC signal.
   (13)

The cleaning method according to any one of (7) to (12), wherein
the impedance adjuster includes at least one of a variable resistor, a variable capacitor, and a variable inductor.
   (14)

A plasma processing apparatus comprising:
a chamber;
a plasma generator that generates plasma in the chamber;
a substrate supporter disposed in the chamber, the substrate supporter including:
a base;
an electrostatic chuck disposed on the base, the electrostatic chuck including a first region having a substrate support surface and a second region disposed outside the first region and having a ring support surface;
a first bias electrode disposed in the first region;
a second bias electrode disposed in the second region; and
an edge ring disposed on the ring support surface;
a bias power supply configured to supply a bias signal to the first bias electrode and the second bias electrode, the bias power supply electrically connected to the first bias electrode and the second bias electrode via a bias transmission line;
an impedance adjusting electrode provided in at least one of the first region or the second region;
an impedance adjuster connected to the impedance adjusting electrode; and
controller circuitry, wherein
the impedance adjusting electrode is grounded via the impedance adjuster, and
the controller circuitry executes:
plasma processing on a substrate on the substrate supporter in the chamber; and
plasma-cleaning on the inside of the chamber by controlling the impedance adjuster to cause a potential in a region in which a member in the chamber to be cleaned is disposed to become higher than a potential in the plasma processing, the region being one of the first region or the second region.
   (15)

The plasma processing apparatus according to (14), wherein
the impedance adjusting electrode is parallel to the first bias electrode at least in the first region,
the plasma-cleaning includes a first plasma cleaning performed in a state where the substrate is supported on the substrate supporter, and
the controller circuitry controls the impedance adjuster such that a potential of the first region becomes lower than a potential of the second region in the first plasma cleaning.
   (16)

The plasma processing apparatus according to (14) or (15), wherein
the impedance adjusting electrode is provided in such a manner as to be parallel to the second bias electrode at least in the second region,
includes second plasma cleaning performed in a state where no substrate is supported on the substrate supporter, and
the controller circuitry controls the impedance adjuster to cause a potential of the second region to become lower than a potential of the first region in the second plasma cleaning.
   (17)

The plasma processing apparatus according to any one of (14) to (16), wherein
the impedance adjuster includes at least one of a variable resistor, a variable capacitor, and a variable inductor.
   (18)

The plasma processing apparatus according to any one of (14) to (17), wherein
the bias signal includes one or more of a high frequency signal and a pulsed DC signal.
   (19)

The plasma processing apparatus according to (14), further comprising an exhaust system connected to a gas discharge port, and
wherein the plasma-cleaning includes controlling the exhaust system to reduce pressure in the chamber to a predetermined pressure.
   (20)

The plasma processing apparatus according to (19), further comprising:
a gas supply including a plurality of gas introduction ports; and
an RF power supply,
   wherein the plasma-cleaning includes controlling gas supply to supply plasma generating gas from the plurality of gas introduction ports to the chamber and controlling the RF power supply to supply power into the chamber to generate plasma in the chamber.

According to the present disclosure, it is possible to suppress wear of members in a chamber while supplying large bias power.

Although the invention has been described with respect to specific embodiments for a complete and clear disclosure, the appended claims are not to be thus limited but are to be construed as embodying all modifications and alternative constructions that may occur to one skilled in the art that fairly fall within the basic teaching herein set forth. The present disclosure encompasses various modifications to each of the examples and embodiments discussed herein. According to the disclosure, one or more features described above in one embodiment or example can be equally applied to another embodiment or example described above. The features of one or more embodiments or examples described above can be combined into each of the embodiments or examples described above. Any full or partial combination of one or more embodiment or examples of the disclosure is also part of the disclosure.

What is claimed is:

1. A cleaning method for a plasma processing apparatus, the method comprising:
a step of supporting a substrate on a substrate support disposed in a chamber, the substrate support comprising a first region supporting the substrate and a second region supporting an edge ring;
a step of adjusting a potential of an impedance adjusting electrode such that a potential of the second region becomes lower than a potential of the first region by controlling an impedance adjuster connected to the impedance adjusting electrode provided in the second region;
a step of supplying a cleaning gas into the chamber;
a step of generating plasma from the cleaning gas by supplying high-frequency power for plasma generation into the chamber; and
a step of cleaning a member in the chamber by supplying bias power into the chamber.

2. The cleaning method according to claim 1, wherein
the bias power causes cleaning of a side wall in the chamber.

3. The cleaning method according to claim 1, wherein
during the step of cleaning, the potential of the impedance adjusting electrode is adjusted depending on the member in the chamber to be cleaned.

4. The cleaning method according to claim 1, wherein
the bias power includes one or more of a high frequency signal and a pulsed DC signal.

5. The cleaning method according to claim 1, wherein
the impedance adjuster includes at least one of a variable resistor, a variable capacitor, and a variable inductor.

6. A cleaning method for a plasma processing apparatus, the method comprising:
in a substrate support disposed in a chamber, the substrate support comprising a first region supporting a substrate and a second region supporting an edge ring, a step of adjusting a potential of an impedance adjusting electrode to cause a potential of the second region to become lower than a potential of the first region, the step of adjusting the potential of the impedance adjusting electrode being performed by controlling an impedance adjuster connected to the impedance adjusting electrode provided in the second region;
a step of supplying a cleaning gas into the chamber;
a step of generating plasma from the cleaning gas by supplying high-frequency power for plasma generation into the chamber; and
a step of cleaning a member in the chamber by supplying bias power into the chamber.

7. The cleaning method according to claim 6, further comprising, after the step of cleaning the member:
a step of carrying out the edge ring from the chamber;
a step of supporting the substrate in the first region; and
a step of adjusting the potential of the impedance adjusting electrode to cause the potential of the first region to become lower than the potential of the second region by controlling the impedance adjuster connected to the impedance adjusting electrode provided in the first region.

8. The cleaning method according to claim 7, further comprising, after adjusting the potential of the impedance adjusting electrode to cause the potential of the first region to become lower than the potential of the second region:
a step of supporting the edge ring in the second region; and
a step of adjusting the potential of the impedance adjusting electrode to cause the potential of the second region become lower than the potential of the first region by controlling the impedance adjuster connected to the impedance adjusting electrode provided in the second region.

9. The cleaning method according to claim 8, further comprising executing a seasoning process by controlling a gas supply to supply plasma generation gas from a plurality of gas introduction ports to the chamber and controlling a power supply to ignite plasma in the chamber.

10. The cleaning method according to claim 6, wherein
the bias power causes cleaning of the first region.

11. The cleaning method according to claim 6, wherein
in the step of cleaning, the potential of the impedance adjusting electrode is adjusted depending on the member in the chamber to be cleaned.

12. The cleaning method according to claim 6, wherein
the bias power includes one or more of a high frequency signal and a pulsed DC signal.

13. The cleaning method according to claim 6, wherein
the impedance adjuster includes at least one of a variable resistor, a variable capacitor, and a variable inductor.

14. A plasma processing apparatus comprising:
a chamber;
a plasma generator that generates plasma in the chamber;
a substrate supporter disposed in the chamber, the substrate supporter including:
a base;
an electrostatic chuck disposed on the base, the electrostatic chuck including:
a first region having a substrate support surface;
a second region disposed outside the first region and having a ring support surface;
a first bias electrode disposed in the first region;
a second bias electrode disposed in the second region; and
an edge ring disposed on the ring support surface;
a bias power supply configured to supply a bias signal to the first bias electrode and the second bias electrode, the bias power supply electrically connected to the first bias electrode and the second bias electrode via a bias transmission line;
an impedance adjusting electrode provided in at least one of the first region or the second region;
an impedance adjuster connected to the impedance adjusting electrode; and
controller circuitry, wherein
the impedance adjusting electrode is grounded via the impedance adjuster, and
the controller circuitry executes:
plasma processing on a substrate on the substrate supporter in the chamber; and
plasma-cleaning on the inside of the chamber by controlling the impedance adjuster to cause a potential in a region in which a member in the chamber to be cleaned is disposed to become higher than a potential in the plasma processing, the region being one of the first region or the second region.

15. The plasma processing apparatus according to claim 14, wherein
the impedance adjusting electrode is parallel to the first bias electrode at least in the first region,
the plasma-cleaning includes a first plasma cleaning performed in a state where the substrate is supported on the substrate supporter, and
the controller circuitry controls the impedance adjuster such that a potential of the first region becomes lower than a potential of the second region in the first plasma cleaning.

16. The plasma processing apparatus according to claim 14, wherein
the impedance adjusting electrode is parallel to the second bias electrode at least in the second region,
includes second plasma cleaning performed in a state where no substrate is supported on the substrate supporter, and
the controller circuitry controls the impedance adjuster to cause a potential of the second region to become lower than a potential of the first region in the second plasma cleaning.

17. The plasma processing apparatus according to claim 14, wherein
the impedance adjuster includes at least one of a variable resistor, a variable capacitor, and a variable inductor.

18. The plasma processing apparatus according to claim 14, wherein
the bias signal includes one or more of a high frequency signal and a pulsed DC signal.

19. The plasma processing apparatus according to claim 14, further comprising an exhaust system connected to a gas discharge port, and
wherein the plasma-cleaning includes controlling the exhaust system to reduce pressure in the chamber to a predetermined pressure.

20. The plasma processing apparatus according to claim 19, further comprising:
a gas supply including a plurality of gas introduction ports; and
an RF power supply,
wherein the plasma-cleaning includes controlling gas supply to supply plasma generating gas from the plurality of gas introduction ports to the chamber and controlling the RF power supply to supply power into the chamber to generate plasma in the chamber.
